(19) United States
(12) Patent Application Publication
(10) Pub. No.: US 2025/0194430 A1
(43) Pub. Date: Jun. 12, 2025

(54) MAGNETIC DEVICE AND A METHOD FOR FORMING THE MAGNETIC DEVICE

(71) Applicants: National University of Singapore, Singapore (SG); Southern University of Science and Technology, Shenzhen (CN)

(72) Inventors: Zhi Shiuh Lim, Singapore (SG); Ariando, Singapore (SG); Changjian Li, Shenzhen City (CN)

(21) Appl. No.: 18/536,524

(22) Filed: Dec. 12, 2023

(30) Foreign Application Priority Data
Dec. 6, 2023 (SG) 10202303436V

(51) Int. Cl. H10N 50/01; G11C 11/16; H10N 50/10; H10N 50/85; H10N 52/85

(52) U.S. Cl. CPC H10N 50/01; G11C 11/161; H10N 50/10; H10N 50/85; H10N 52/85

(57) ABSTRACT

A magnetic device includes a magnetic layer having a ferromagnetic phase to support magnetic skyrmions and an antiferromagnetic phase to annihilate magnetic skyrmions. The magnetic layer transmits between the ferromagnetic and antiferromagnetic phases. A ferroelectric layer is adapted to magnetoelectrically couple with the magnetic layer causing the magnetic layer to transit between the ferromagnetic and antiferromagnetic phases in response to a polarization state of the ferroelectric layer. The polarization state includes a first polarization state corresponding to the ferromagnetic state and a second polarization state corresponding to the antiferromagnetic state. First and second electrodes can be configured to sandwich the magnetic and ferroelectric layers. The first and second electrodes can be adapted to receive applied voltage for switching the polarization state of the ferroelectric layer to control a phase transition of the magnetic layer between the ferromagnetic and antiferromagnetic phases to create or annihilate magnetic skyrmions in the magnetic layer.

### RELATED APPLICATION

This application claims priority under 35 U.S.C. § 119 or 365 to Singapore Application No. 10202303436V, filed Dec. 6, 2023, the entire teachings of which are incorporated herein by reference.

### TECHNICAL FIELD

The present disclosure relates to a magnetic device and a method for forming the magnetic device.

### BACKGROUND

Statistical projection shows that by 2025, the information technology sector alone would consume up to 20% of the total electricity produced worldwide and contribute up to 5.5% of the world's carbon emissions. Hence, reducing energy consumption has become the primary concern in the development of next-generation computational and data storage devices. The spintronic research field largely aims at building non-volatile magnetic random-access memory (MRAM) to replace the former volatile static random-access memory (SRAM) and dynamic random-access memory (DRAM) variants so that the possibility of memory loss and their requirement of periodic refreshing can be avoided. In MRAM, controlling the state of a ferromagnetic domain memory cell by electric current via the spin-transfer torque (STT) or spin-orbit torque (SOT) mechanism is of paramount importance for device miniaturization. Yet, the high current densities involved in switching collinear magnetic domain (˜10¹⁰-10¹¹ A/m²) still suffer a significant bottleneck.

Interests in building racetrack memories based on magnetic skyrmions in replacement of collinear domains have surfaced, stemming from the discovery where a much lower threshold current density (J_{C}˜10⁶ A/m²) is needed for initiating skyrmions' motion attributed to their topological property playing a crucial role in evading domain-pinning resulted from impurities. In parallel, magnetoelectric coupling, i.e. manipulation of magnetic properties by an electric field, or a narrower non-volatile subset i.e. multiferroicity, are actively pursued to address issues related to the usage of electric current and Joule heating. Intrinsic bulk multiferroic materials such as the Bi-based perovskites (BiFeO₃, BiMnO₃) have led to the demonstration of tuning exchange bias with an adjacent ferromagnet and a 4-state tunnelling junction. Bismuth-based perovskites such as BiFeO₃, BiMnO₃ and derivatives, as well as the Cu₂OSeO₃ that supports Bloch-type skyrmions, are among the few bulk multiferroic candidates. However, having an ideal multiferroic material that fulfils simultaneously all desired qualities such as low leakage current, room-temperature ferromagnetism, high polarization etc., is difficult. On the other hand, strain-induced tuning of metallic Néel-type skyrmions by a large-d₃₃ ferroelectric such as the Pb_{0.64}(Mg_{1/3}Nb_{2/3})O₃—Pb_{0.36}TiO₃ (PMN-PT) is being investigated since carrier density modulation by electric field effect would not be effective in metallic multilayer stacks. However, strain-induced tuning shows a weak and mixed response because changing strain will tune both the Dzyaloshinskii-Moriya interaction (DMI) and anisotropy factors, resulting in a cancellation of an overall effect thereby causing a net effect on skyrmions to be weak and probably stochastic. Further, strain-induced tuning may have a limited range and switching speed, rendering it not so effective particularly for applications in memory devices.

It is therefore desirable to provide a magnetic device and a method for forming a magnetic device which address the aforementioned problems and/or provides a useful alternative. Further, other desirable features and characteristics will become apparent from the subsequent detailed description and the appended claims, taken in conjunction with the accompanying drawings and this background of the disclosure.

### SUMMARY

Aspects of the present application relate to a magnetic device and a method of forming the magnetic device.

In accordance with a first aspect, there is provided a magnetic device comprising: a magnetic layer having a ferromagnetic phase to support magnetic skyrmions and an antiferromagnetic phase to annihilate magnetic skyrmions, the magnetic layer being capable of transiting between the ferromagnetic phase and the antiferromagnetic phase; a ferroelectric layer adapted to magnetoelectrically couple with the magnetic layer to cause the magnetic layer to transit between the ferromagnetic phase and the antiferromagnetic phase in response to a polarization state of the ferroelectric layer, the polarization state includes a first polarization state corresponding to the ferromagnetic state and a second polarization state corresponding to the antiferromagnetic state; and a first electrode and a second electrode sandwiching the magnetic layer and the ferroelectric layer, the first electrode and the second electrode being adapted to receive an applied voltage for switching the polarization state of the ferroelectric layer to control a phase transition of the magnetic layer between the ferromagnetic phase and the antiferromagnetic phase to create or annihilate magnetic skyrmions in the magnetic layer.

By comprising (i) a magnetic layer having a ferromagnetic phase to support magnetic skyrmions and an antiferromagnetic phase to annihilate magnetic skyrmions, and (ii) a ferroelectric layer adapted to magnetoelectrically couple with the magnetic layer to cause the magnetic layer to transit between the ferromagnetic phase and the antiferromagnetic phase in response to a polarization state of the ferroelectric layer controlled by an application of an applied voltage, the magnetic device is adapted to create or annihilate magnetic skyrmions in the magnetic layer with the application of an applied voltage. The aforementioned magnetic device can therefore act as a logic gate for non-volatile memory, with the magnetic skyrmions being memory bits. The applied voltage can be used to create or annihilate the magnetic skyrmions to perform logic operations. The applied voltage, for example a short-pulsed voltage, consumes very little energy (e.g. in the range of femto-Joule or atto-Joule per operation) and therefore reduces the energy required to operate the magnetic device. The creation or annihilation of magnetic skyrmions by a pulsed voltage eliminates the need to use a large current for magnetic phase/state switching as compared to other switching mechanisms such as spin-transfer torques (STT) and spin-orbit torques (SOT) used in conventional magnetic memory devices.

The magnetic layer may include a (La,Ba)MnO₃ (LBMO) layer and the ferroelectric layer may include a lead zirconate titanate (PZT) layer. Magnetoelectric coupling between the LBMO layer and the PZT layer provides an interfacial effect between two non-multiferroic materials which circumvents a scarcity problem of ideal multiferroics. Further, magnetic skyrmions can be created and annihilated by controlling a polarization state of the PZT layer at high temperatures up to 275 Kelvin (K).

The magnetic layer may comprise La_{0.5}Ba_{0.5}MnO₃ having a thickness from 2.0 nm to 2.8 nm. At this composition where x=0.5, the La_{0.5}Ba_{0.5}MnO₃ magnetic layer qualifies as a Mott insulator. Coupled with being ultrathin within a range of 2.0 nm to 2.8 nm, this La_{0.5}Ba_{0.5}MnO₃ magnetic layer is adapted to improve magnetoelectric coupling via carrier density modulation, making it more effective with lowered threshold voltages.

The first electrode (e.g. a top electrode) may be formed adjacent to the magnetic layer and the second electrode (e.g. a bottom electrode) may be formed adjacent to the ferroelectric layer, and the first electrode may include a platinum (Pt) layer. Due to strong spin-orbit coupling, the Pt layer formed adjacent to the magnetic layer (e.g. a LBMO layer) contributes to an interfacial Dzyaloshinskii-Moriya interaction (DMI) for creating chiral magnetic ordering and Néel-type skyrmions in the magnetic layer, and stabilizing magnetic skyrmions in the magnetic layer. Further, free electrons in the Pt layer interact strongly with magnetic moments in the magnetic layer via the magnetic proximity effect (MPE) and the Spin Hall Effect (SHE).

The second electrode may include a monostrontium ruthenate (SrRuO₃) layer. In an embodiment, the SrRuO₃ layer has a high conductivity among perovskite oxides and can be epitaxially matched with the PZT layer. Further, the SrRuO₃ layer has a ferromagnetic Curie temperature (T_{C}) of at most 150 K, thereby avoiding any unwanted magnetic interactions with the LBMO layer of the magnetic device.

The platinum layer and the magnetic layer may be patterned in a form of a Hall bar to measure a Hall effect in the magnetic layer. The Hall bar formed enables electrical measurement of magnetic skyrmions via the Topological Hall Effect (THE). Further, measurements using the Hall bar provides an all-electrical process consistent with the read-write operations in memory devices, and does not require imaging of magnetic skyrmions.

The magnetic device may comprise a SrTiO₃ (001) substrate, wherein the magnetic layer, the ferroelectric layer, the first electrode and the second electrode may be formed on the SrTiO₃ (001) substrate.

The magnetic layer may be formed immediately adjacent to the ferroelectric layer.

In accordance with a second aspect, there is provided a method for forming a magnetic device. The method comprising: forming a magnetic layer having a ferromagnetic phase to support magnetic skyrmions and an antiferromagnetic phase to annihilate magnetic skyrmions, the magnetic layer being capable of transiting between the ferromagnetic phase and the antiferromagnetic phase; forming a ferroelectric layer adapted to magnetoelectrically couple with the magnetic layer to cause the magnetic layer to transit between the ferromagnetic phase and the antiferromagnetic phase in response to a polarization state of the ferroelectric layer, the polarization state includes a first polarization state associated with the ferromagnetic state and a second polarization state associated with the antiferromagnetic state; and forming a first electrode and a second electrode sandwiching the magnetic layer and the ferroelectric layer, the first electrode and the second electrode being adapted to receive an applied voltage for altering the polarization state of the ferroelectric layer to control a phase transition of the magnetic layer between the ferromagnetic phase and the antiferromagnetic phase to create or annihilate magnetic skyrmions in the magnetic layer.

Where the magnetic layer may include a (La,Ba)MnO₃ (LBMO) layer and the ferroelectric layer may include a lead zirconate titanate (PZT) layer, forming the magnetic layer and forming the ferroelectric layer may include pulsed laser depositing the (La,Ba)MnO₃ (LBMO) layer and pulsed laser depositing the lead zirconate titanate (PZT) layer in-situ.

The magnetic layer may comprise La_{0.5}Ba_{0.5}MnO₃ having a thickness from 2.0 nm to 2.8 nm.

The method may comprise forming the first electrode (e.g. a top electrode) adjacent to the magnetic layer and forming the second electrode (e.g. a bottom electrode) adjacent to the ferroelectric layer, wherein the first electrode may include a platinum (Pt) layer. The second electrode may include a monostrontium ruthenate (SrRuO₃) layer.

The method may comprise patterning the platinum layer and the magnetic layer in a form of a Hall bar for measuring a Hall effect in the magnetic layer.

The method may comprise forming the platinum layer by sputtering, wherein the platinum layer may have a thickness in a range from 2 nm to 5 nm.

The method may comprise forming the magnetic layer, the ferroelectric layer, the first electrode and the second electrode on a SrTiO₃ (001) substrate.

The method may comprise forming the magnetic layer immediately adjacent to the ferroelectric layer.

It should be appreciated that features relating to one aspect may be applicable to the other aspects. Embodiments provide a magnetic device and a method of forming a magnetic device. Particularly, by comprising (i) a magnetic layer having a ferromagnetic phase to support magnetic skyrmions and an antiferromagnetic phase to annihilate magnetic skyrmions, and (ii) a ferroelectric layer adapted to magnetoelectrically couple with the magnetic layer to cause the magnetic layer to transit between the ferromagnetic phase and the antiferromagnetic phase in response to a polarization state of the ferroelectric layer controlled by an application of an applied voltage, the magnetic device is adapted to create or annihilate magnetic skyrmions in the magnetic layer with the application of an applied voltage. The aforementioned magnetic device can therefore act as a logic gate for non-volatile memory, with the magnetic skyrmions being memory bits. The applied voltage can be used to create or annihilate the magnetic skyrmions to perform logic operations.

The applied voltage, for example a short-pulsed voltage, consumes very little energy (e.g. in the range of femto-Joule or atto-Joule per operation) and therefore reduces the energy required to operate the magnetic device. The creation and annihilation of magnetic skyrmions by pulsed voltage eliminates the need to use large current for magnetic phase/state switching as compared to other switching mechanisms such as spin-transfer and spin-orbit torques (STT and SOT) used in conventional magnetic memory devices.

In embodiments where the magnetic layer includes a LBMO layer and the ferroelectric layer includes a PZT layer, magnetoelectric coupling between the LBMO layer and the PZT layer provides an interfacial effect between two non-multiferroic materials which circumvents a scarcity problem of ideal multiferroics. Further, magnetic skyrmions can be created and annihilated by controlling a polarization state of the PZT layer at high temperatures up to 275 Kelvin. In embodiments where the magnetic layer comprises La_{0.5}Ba_{0.5}MnO₃ and having a thickness from 2.0 nm to 2.8 nm, the La_{0.5}Ba_{0.5}MnO₃ magnetic layer acts as a Mott insulator at this composition where x=0.5. Coupled with being ultrathin within a range of 2.0 nm to 2.8 nm, this La_{0.5}Ba_{0.5}MnO₃ magnetic layer is adapted to improve magnetoelectric coupling via carrier density modulation, making creation and annihilation of skyrmions La_{0.5}Ba_{0.5}MnO₃ magnetic layer more effective with lower threshold voltages. Further, in embodiments where the first electrode (e.g. a top electrode) is formed adjacent to the magnetic layer and include a platinum (Pt) layer, the Pt layer formed adjacent to the magnetic layer (e.g. a LBMO layer) contributes to an interfacial Dzyaloshinskii-Moriya interaction (DMI) for creating chiral magnetic ordering and Néel-type skyrmions in the magnetic layer due to a strong spin-orbit coupling at the Pt/magnetic layer interface. Further, the free electrons of the Pt layer interact strongly with magnetic moments in the magnetic layer via the magnetic proximity effect (MPE) and the Spin Hall Effect (SHE). Still further, in embodiments where the ferroelectric layer includes a PZT layer and the second electrode (e.g. a bottom electrode) includes a monostrontium ruthenate (SrRuO₃) layer, the SrRuO₃ layer can be epitaxially matched with the PZT layer to minimise growth defects of subsequent growth of the PZT layer on the SrRuO₃ layer. Moreover, the SrRuO₃ layer has a ferromagnetic Curie temperature of at most 150 K, thereby avoiding any unwanted magnetic interactions with the LBMO layer of the magnetic device.

### BRIEF DESCRIPTION OF THE DRAWINGS

The foregoing will be apparent from the following more particular description of example embodiments, as illustrated in the accompanying drawings in which like reference characters refer to the same parts throughout the different views. The drawings are not necessarily to scale, emphasis instead being placed upon illustrating embodiments.

Embodiments will now be described, by way of example only, with reference to the following drawings, in which:

FIG. 1 is a schematic diagram showing a planar cross-section of a magnetic device comprising a magnetic layer and a ferroelectric layer sandwiched between a top electrode and a bottom electrode formed on a substrate in accordance with an embodiment;

FIG. 2 is a flowchart showing a method for forming the magnetic device of FIG. 1 in accordance with an embodiment;

FIGS. 3A and 3B show graphs to illustrate Hall effect of platinum/(La,Ba)MnO₃ (Pt/LBMO) bilayers where FIG. 3A includes a graph of ρ_{xy} versus magnetic field μ₀H for different temperatures and FIG. 3B includes a graph of ρ_{xy} versus magnetic field μ₀H for different magnetic field angle (θ) at a temperature of 250 K in accordance with an embodiment;

FIG. 4 shows a simulated mapping of two-dimensional topological charge density (TCD) versus magnetic field angle (θ) and magnetic field μ₀H in accordance with an embodiment;

FIGS. 5A and 5B show schematic diagrams to illustrate formation of the magnetic device of FIG. 1 in accordance with an embodiment, where FIG. 5A shows a schematic diagram to illustrate formation of the bottom electrode on the substrate and FIG. 5B shows a schematic diagram to illustrate formation of the ferroelectric layer, the magnetic layer and the top electrode on the bottom electrode and the substrate for forming the magnetic device;

FIG. 6 shows an optical micrograph of a top planar view of the magnetic device of FIG. 5B comprising a Hall structure in accordance with an embodiment;

FIGS. 7A, 7B, 7C and 7D show experimental results obtained in relation to the heterostructure Pt/LBMO/PZT/SrRuO₃/SrTiO₃ (001) for investigating material quality of this heterostructure in accordance with an embodiment, where FIG. 7A shows a 2 Theta-Omega (2θ-ω) X-ray diffraction (XRD) scan around (002) of the heterostructure, FIG. 7B shows an atomic force microscopy (AFM) topography scan of the heterostructure, FIG. 7C shows a XRD reciprocal space mapping of the heterostructure for the (−103) crystallographic plane and FIG. 7D shows a XRD reciprocal space mapping of the heterostructure for the (−204) crystallographic plane;

FIG. 8 shows a graph of polarization versus voltage loops measured across a PZT layer with varying PZT thickness, pulse widths and pulse magnitude in accordance with an embodiment;

FIGS. 9A, 9B and 9C show experimental results in relation to ferroelectric switching of a PZT layer of the magnetic device of FIG. 5B in accordance with an embodiment, where FIG. 9A shows a graph of polarization versus voltage of the PZT layer for different temperatures, FIG. 9B shows a graph of remnant polarization (Pᵣ) versus temperature as extracted from the graph of FIG. 9A and FIG. 9C shows a graph of coercive voltage (V_{C}) versus temperature as extracted from the graph of FIG. 9A;

FIG. 10 shows graphs of p_{xy} versus magnetic field μ₀H to illustrate Hall effect tuning by switching ferroelectric polarization of the PZT layer of the magnetic device of FIG. 5B using a voltage pulse having a pulse width of 0.2 ms at temperatures of 150 K, 200 K, 250 K and 300 K in accordance with an embodiment;

FIG. 11 shows a graph of Topological Hall Effect (THE) resistivity versus an applied voltage across a PZT layer of the magnetic device of FIG. 5B at a temperature of 175 K in accordance with an embodiment;

FIG. 12 shows a graph of THE resistivity versus temperature for a 2.0 nm thick (i.e. 5 u.c.) LBMO layer and for a 2.8 nm thick (i.e. 7 u.c.) LBMO layer at applied voltages of +3V and −3V in accordance with an embodiment;

FIGS. 13A, 13B, 13C and 13D show experimental results obtained using scanning transmission electron microscopy (STEM) of a heterostructure Pt/LBMO/PZT/SRO of a magnetic device in accordance with an embodiment, where FIG. 13A shows an energy dispersion spectroscopy (EDS) mapping of a cross-section of the heterostructure, FIG. 13B shows a high-angle annular dark field (HAADF) imaging of a cross-section of the heterostructure, FIG. 13C shows a cationic displacement mapping near the LBMO/PZT interface of the heterostructure and FIG. 13D shows a cationic displacement mapping near the PZT/SRO interface of the heterostructure; and

FIGS. 14A, 14B, 14C and 14D show diagrams to illustrate a mechanism of the LBMO/PZT magneto-electric response in accordance with an embodiment, where FIG. 14A shows a schematic diagram to illustrate a first scenario where polarization of the PZT layer is pointing away from the LBMO layer, FIG. 14B shows a schematic diagram to illustrate a second scenario where polarization of the PZT layer is pointing towards the LBMO layer, FIG. 14C shows a graph of simulated topological charge density (TCD) versus magnetic field μ₀H_{z} for the first scenario as shown in relation to FIG. 14A, and FIG. 14D shows a graph of simulated topological charge density (TCD) versus magnetic field μ₀H_{z} for the second scenario as shown in relation to FIG. 14B.

### DETAILED DESCRIPTION

A description of example embodiments follows.

Exemplary embodiments relate to a magnetic device and a method for forming a magnetic device.

Particularly, the magnetic device of the present embodiments includes (i) a magnetic layer having a ferromagnetic phase to support magnetic skyrmions and an antiferromagnetic phase to annihilate magnetic skyrmions and (ii) a ferroelectric layer adapted to magnetoelectrically couple with the magnetic layer to cause the magnetic layer to transit between the ferromagnetic phase and the antiferromagnetic phase in response to a polarization state of the ferroelectric layer controlled by an application of an applied voltage. In this way, an electrical handle is provided to manipulate a magnetic state/phase of the magnetic layer by creating or annihilating magnetic skyrmions in the magnetic layer via changing of the polarization state of the ferroelectric layer. The magnetic skyrmions can be used as memory bits, thereby enabling the aforementioned magnetic device to perform as a logic gate for non-volatile memory applications.

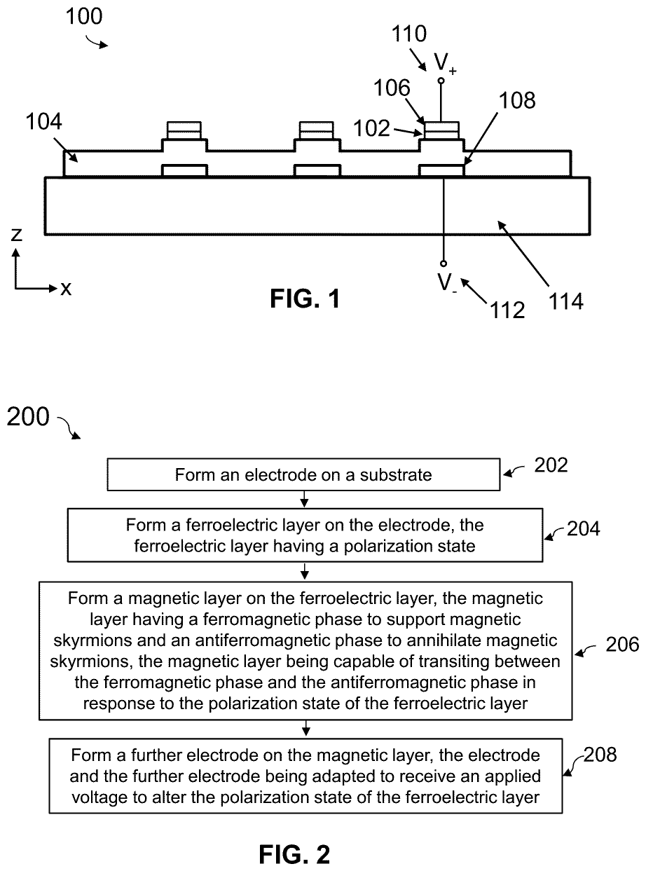

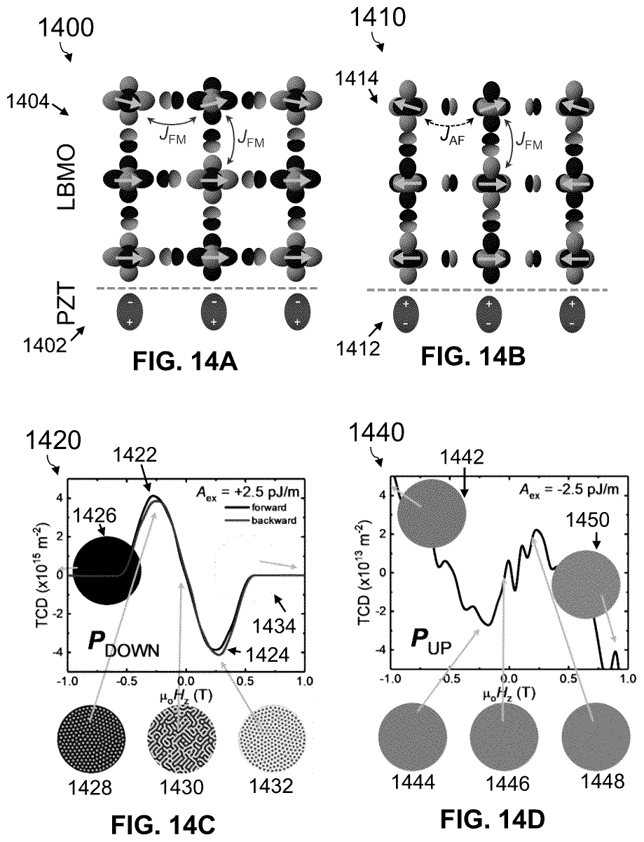

FIG. 1 is a schematic diagram showing a planar cross-section of a magnetic device 100. The magnetic device 100 comprises a magnetic layer 102 formed on a ferroelectric layer 104. In the present embodiment as shown in relation to FIG. 1, the magnetic layer 102 is formed immediately adjacent to the ferroelectric layer 104. The magnetic layer 102 is adapted to transit between a ferromagnetic phase and an antiferromagnetic phase, where the ferromagnetic phase is capable of supporting magnetic skyrmions and the antiferromagnetic phase is capable of annihilating magnetic skyrmions in the magnetic layer 102. The magnetic layer 102 is therefore configured to transit between two magnetic states/phases. The ferroelectric layer 104 is adapted to magnetoelectrically couple with the magnetic layer 102 to cause the magnetic layer to transit between the ferromagnetic phase and the antiferromagnetic phase in response to a polarization state of the ferroelectric layer 104. In an embodiment, the down polarization state (P_{DOWN}) is associated with the ferromagnetic phase where magnetic skyrmions are created and the up polarization state (P_{UP}) is associated with the antiferromagnetic phase where magnetic skyrmions are annihilated. The mechanism for these will be explained below in relation to FIGS. 14A and 14B.

The magnetic device 100 further comprises a top electrode (i.e. a first electrode) 106 and a bottom electrode (i.e. a second electrode) 108 adapted to receive an applied voltage for switching the polarization state of the ferroelectric layer 104 to control a phase transition of the magnetic layer 102 between the ferromagnetic phase and the antiferromagnetic phase to create or annihilate magnetic skyrmions in the magnetic layer 102. In the present embodiment, the top electrode 106 is formed on and adjacent to the magnetic layer 102, while the bottom electrode 108 is formed underneath (or below) and adjacent to the ferroelectric layer 104 such that the top electrode 106 and the bottom electrode 108 are sandwiching the magnetic layer 102 and the ferroelectric layer 104. It should be appreciated that other arrangements of the top electrode 106 and/or the bottom electrode 108 are possible as long as an electric field can be applied across the ferroelectric layer 104 and the magnetic layer 102 to switch the polarization state of the ferroelectric layer 104. In the present embodiment, a positive potential (V₊) 110 (e.g. in the form of a positive voltage pulse) is shown to be applied to the top electrode 106 and a negative potential (V.) 112 (e.g. in the form of a negative voltage pulse) is shown to be applied to the bottom electrode 108, but it should be appreciated that the polarity of each of these potentials can be reversed so as to change a direction of the electric field being applied across the ferroelectric layer 104 for varying the polarization of the ferroelectric layer 104. In an exemplary embodiment as discussed below, the magnetic layer 102 includes a ferromagnetic layer such as a LBMO layer, the ferroelectric layer 104 includes a PZT layer, the top electrode 106 includes a heavy metal such as Pt and the bottom electrode 108 includes a metallic perovskite oxide such as SrRuO₃ (SRO). In the present embodiment, the magnetic layer 102, the ferroelectric layer 104, the top electrode 106 and the bottom electrode 108 are formed on a substrate 114. The substrate 114 provides mechanical support for the magnetic device 100. In the exemplary embodiment, the substrate 114 includes a perovskite oxide substrate, such as a SrTiO₃ (STO) (001) substrate.

FIG. 2 is a flowchart showing a method 200 for forming the magnetic device 100 of FIG. 1 in accordance with an embodiment.

In a step 202, an electrode (i.e. the bottom electrode 108) is formed on the substrate 114. In an embodiment, one or more electrodes 108 are formed on the substrate 114 in the form of stripes.

In a step 204, the ferroelectric layer 104 is formed on the bottom electrode 108. The ferroelectric layer 104 having a polarization state dependent on an electric field applied across the ferroelectric layer 104.

In a step 206, the magnetic layer 102 is formed on the ferroelectric layer 104, the magnetic layer 102 having a ferromagnetic phase to support magnetic skyrmions and an antiferromagnetic phase to annihilate magnetic skyrmions. The magnetic layer 102 is adapted to magnetoelectrically couple with the ferroelectric layer 104, and is capable of transiting between the ferromagnetic phase and the antiferromagnetic phase in response to the polarization state of the ferroelectric layer 104. The polarization state of the ferroelectric layer 104 includes a first polarization state associated with the ferromagnetic state and a second polarization state associated with the antiferromagnetic state.

In a step 208, a further electrode (i.e. the top electrode 106) is formed on the magnetic layer 102. The top electrode 106 and the bottom electrode 108 are adapted to receive an applied voltage for altering the polarization state of the ferroelectric layer 104 to control a phase transition of the magnetic layer 102 between the ferromagnetic phase and the antiferromagnetic phase to create or annihilate magnetic skyrmions in the magnetic layer 102.

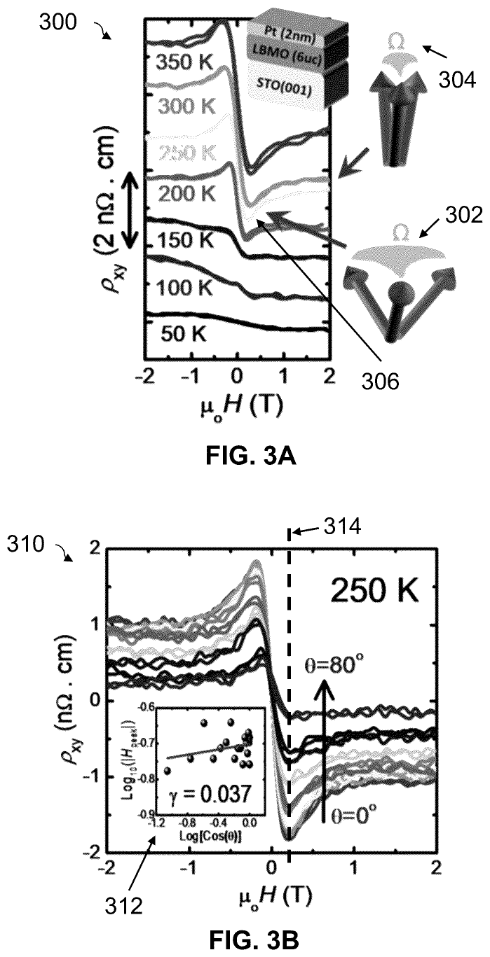

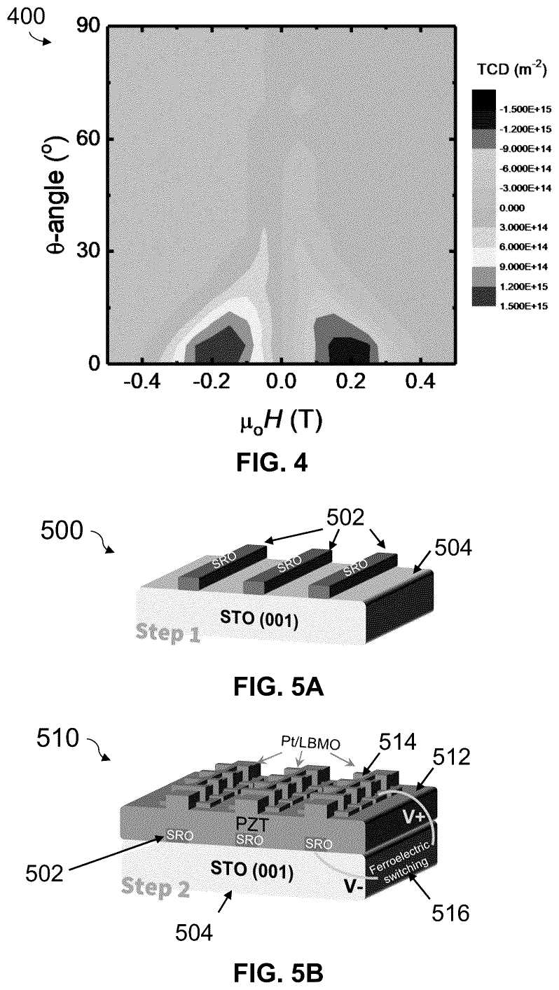

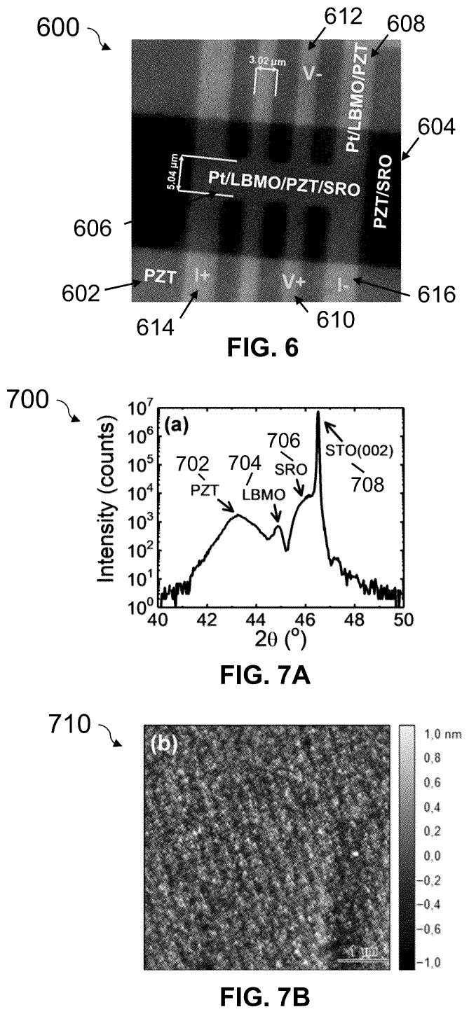

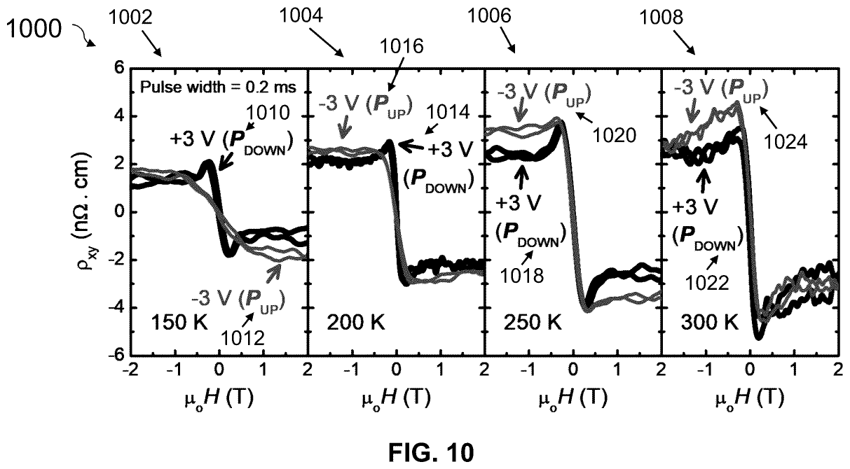

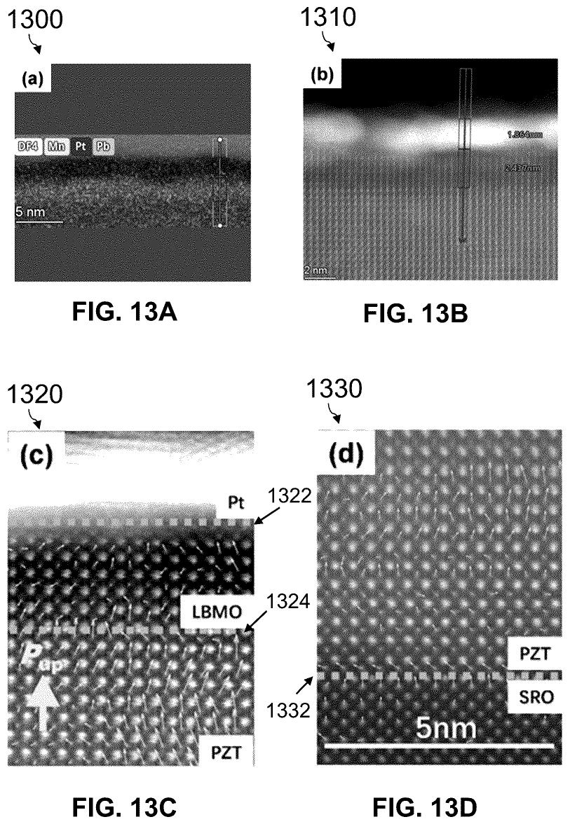

In an exemplary embodiment, a Pt/La_{0.5}Ba_{0.5}MnO₃/PbZr_{0.2}Ti_{0.8}O₃/SrRuO₃ (Pt/LBMO/PZT/SRO) heterostructure grown on a SrTiO₃ (001) substrate was used to form a magnetic device. FIGS. 3A, 3B and 4 below are used to illustrate the presence of magnetic skyrmions in a Pt/LBMO bilayer using the Topological Hall Effect (THE), FIGS. 5A and 5B show a “two-step” fabrication process of the magnetic device, FIGS. 6 to 9C relates to characterization of the heterostructure to illustrate a material quality as well as working of the polarization of the ferroelectric layer, FIGS. 10 to 12 relate to tuning of the THE by altering a polarization state of the ferroelectric layer, and FIGS. 13A to 14D illustrate atomic structure evidence and simulation results relating to a mechanism of the LBMO/PZT response.

FIGS. 3A and 3B show graphs to illustrate Hall effect of a Pt/LBMO bilayer. In this Pt/LMBO bilayer, the Pt layer used is about 2 nm thick while the LBMO layer used is about 2.4 nm thick (i.e. about 6 unit cells (u.c.)). The Pt/LMBO bilayer was formed on a SrTiO₃ (001) substrate layer.

FIG. 3A shows a graph 300 of resistivity ρ_{xy} versus magnetic field μ₀H for different temperatures, from 50 K to 350 K. The resistivity ρ_{xy} provides a measure of the anomalous Hall effect (AHE) in this Pt/LMBO bilayer. FIG. 3A also shows the solid angles Ω 302, 304 subtended by neighbouring magnetic moments, which are related to the topological charge density of magnetic skyrmions, to illustrate an evolution of the topological Hall effect (THE) (a subset of AHE) from a low applied magnetic field μ₀H of about 0.2 T to a positive magnetic field of around 2 T.

The AHE arises from spin-Hall-related magnetic proximity effect (MPE), spanning across a wide temperature range as shown in the graph 300. It typically follows a ρ_{AHE} ∝(T−T_{C})^{-a} power-law divergence trend with temperature, thereby reaching its strongest at the Curie temperature (T_{C}) of the LBMO layer at around 300 K. Where magnetic skyrmion imaging is not readily available (e.g. due to weak magnetization below typical limits of the relevant imaging instruments) or desirable, a hump-shape signal (e.g. as shown at 306 of the graph 300) in an AHE resistivity ρ_{xy} versus magnetic field μ₀H plot is well-accepted as the topological subset of AHE (i.e. THE) for indicating the presence of magnetic skyrmions.

Topological Hall effect (THE) arises from mobile electrons interacting with skyrmions by spin-moment exchange (\hat{σ}·\hat{m}) which does not require spin-orbit coupling (SOC) in electron deflection, unlike the Karplus-Luttinger (KL) subset of AHE for collinear magnetizations. THE produces the hump-shape which indicates the formation of peak skyrmion density with the net solid angle (Ω) 302 subtended by a chiral arrangement of neighbouring magnetic moments \hat{m}ᵢ·(\hat{m}ⱼ×\hat{m}ₖ) before gradually saturating into collinear magnetization with, for example, the solid angle (Ω) 304.

To rule out the possibility that the humps were being reproduced artificially by two sigmoidal KL-AHE of opposite signs, a magnetic field θ-angle rotation Hall measurement for the Pt/LBMO bilayer was performed. The magnetic field was rotated from out-of-plane at θ=0° to in-plane at θ=90° of the Pt/LBMO bilayer.

FIG. 3B includes a graph 310 of ρ_{xy} versus magnetic field μ₀H for different magnetic field angle (θ) at a temperature of 250 K in accordance with an embodiment for ruling out the possibility of the THE hump signature being artificially reproduced by two sigmoidal KL-AHE of opposite signs. The inset 312 shows an extraction of its (near-zero) γ-exponent based on the convention of μ₀Hₚₑₐₖ∝ cos^{Y}(θ). The magnetic field angle (θ) is measured with respect to the z-axis so that θ=0° is out-of-plane to the Pt/LBMO bilayer (i.e. along the z-axis, see e.g. FIG. 1) and that θ=90° is in-plane to the Pt/LBMO bilayer (i.e. the x-y plane, see e.g. FIG. 1). The results as shown in relation to the graph 310 demonstrates that the magnitude of the magnetic fields for the hump-peak is stationary with varying magnetic field angle θ (see e.g. the inset 312 and line 314), which is consistent with a skyrmion-lattice behaviour and the simulation results as shown in FIG. 4 below. In contrast, the magnetic fields for hump peaks (Hₚₑₐₖ) arising from two overlapping KL-AHE are expected to diverge following a 1/cos^{Y}(θ) trend, where γ>0 is a scaling exponent. Therefore, it is evidenced that the hump-peaks observed for the Pt/LBMO bilayer are due to the formation of peak magnetic skyrmion density in the LBMO magnetic layer.

The non-divergent behaviour of Hₚₑₐₖ is consistent with the Ginzburg-Landau's framework where skyrmions (triple-q spin-wave superposition) will be elongated and annihilated by the in-plane magnetic field component into single-q stripes and can be shown by a MUMAX micromagnetic simulation mapping of two-dimensional topological charge density

$$( TCD ) = \hat{m} \cdot ( \frac{d \hat{m}}{dx} \times \frac{d \hat{m}}{dy} )$$

versus magnetic field angle θ and total magnetic field.

FIG. 4 shows a simulated mapping 400 of two-dimensional topological charge density (TCD) versus magnetic field angle (θ) and magnetic field μ₀H in accordance with an embodiment.

The simulated mapping 400 was performed using MUMAX micromagnetic simulation, and the simulation parameters used are: (i) Aₑₓ=4.27 pJ/m; (ii) Mₛₐₜ=313.69 kA/m; (iii) Kᵤ=10 kJ/m³; (iv) D_{ind}=0.6 mJ/m²; (v) α_{G}=0.1; and (vi) B=μ₀H [0, sin(θ), cos(θ)].

The above parameters were estimated as follow: (i) Aₑₓ was estimated using the equation

$${A}_{ex} = \frac{3 {k}_{B} {T}_{C}}{2 j ( j + 1 ) a}$$

where T_{C} is assumed to be ˜300 K, j=3/2 due to the at least 3 μ_{B}/Mn and lattice parameter a=3.88 Å; (ii) With the mean field theory extension to the Langevin's paramagnetism, the temperature dependence of magnetization typically follows

$${M}_{sat} ( T ) / {M}_{sat} ( 0 K ) = tanh ( \frac{{M}_{sat} ( T ) / {M}_{sat} ( 0 K )}{T / {T}_{C}} ) .$$

With Mₛₐₜ at a temperature of 0 K=3μ_{B}/a³=476.3 kA/m, yielding Mₛₐₜ=313.69 kA/m at 250 K; (iii) K_{U} and (iv) interfacial DMI (D_{ind}) are arbitrarily adjusted to match the peak TCD field with the experimentally measured peak THE fields at a rotation angle θ=0°; and (vi) B=μₒH [0, sin(θ), cos(θ)] with swapping the x- and y-axes in the magnetic field vector in B=μₒH [0, sin(θ), cos(θ)] producing the same result. The Gilbert damping coefficient, α_{G} of 0.1 has been used as an acceptable estimation as most ferromagnets have α_{G} in the order of magnitude around 0.1.

The simulated mapping 400 showing the non-diverging behaviour of peak-TCD fields and magnetic skyrmions' phase space provides further support to FIG. 3B above, attesting that the hump-peaks observed for the Pt/LBMO bilayer are due to the formation of peak magnetic skyrmion density.

Following the above, Pt/La_{0.5}Ba_{0.5}MnO₃ (Pt/LBMO) bilayer films were formed on a ferroelectric PbZr_{0.2}Ti_{0.8}O₃(PZT) layer to access the effect of ferroelectric polarization switching on the LBMO layer. In an exemplary embodiment, a Pt/La_{0.5}Ba_{0.5}MnO₃/PbZr_{0.2}Ti_{0.8}O₃/SrRuO₃ (Pt/LBMO/PZT/SRO) heterostructure grown on a SrTiO₃ (001) substrate was formed, and a magnetic device having a Hall bar structure was fabricated. In the present embodiment, a 2 nm thick Pt layer was formed on a 2.4 nm thick LBMO layer to form a bilayer structure. This bilayer structure was formed on a heterostructure comprising a 40 nm thick PZT layer formed on a 14 nm thick SRO layer atop a STO (001) substrate (i.e. PZT (40 nm)/SRO (14 nm)//SrTiO₃ (001)). In the present embodiments, the bilayer structure Pt/LBMO was fabricated into Hall bars.

FIGS. 5A and 5B show schematic diagrams to illustrate formation of the magnetic device of FIG. 1 in accordance with an embodiment. The magnetic device with a Hall bar structure was formed following a two-step fabrication process as shown in relation to FIGS. 5A and 5B.

In the present embodiments, the Pt/LBMO/PZT/SRO heterostructure was deposited in a pulsed laser deposition (PLD) chamber with a load-lock, which was modified to connect to a home-built DC magnetron sputtering via the load-lock to achieve in-situ transfer of samples between the PLD and the sputtering chambers. The PLD chamber, the load-lock and the sputtering chambers all have a base vacuum lower than 5×10⁻⁷ Torr. The PLD chamber has a non-contact convection/radiation heating mode with a ˜0.5 cm gap between the heating coil and the substrate. Such design eases sample transfer and prolongs hardware lifetime. It is noted that the actual temperatures are typically lower than the temperature set-points by less than 100° C. The target-to-substrate distance in the PLD was optimally fixed at 7 cm.

FIG. 5A shows a schematic diagram 500 to illustrate a first step of the two-step fabrication process where SRO electrodes 502 (c.f. the bottom electrode 108 of FIG. 1) were formed on the STO (001) substrate 504 (c.f. the substrate 114 of FIG. 1).

In this exemplary embodiment, in the first step of the two-step fabrication process, a 14 nm-thick single-crystalline SRO thin film was grown in the PLD chamber on a commercially available STO (001) substrate at a temperature of 650° C. and at a purified oxygen pressure (P_{O2}) of 100 mTorr to sustain the step-flow growth mode. The SRO thin film was chosen as the bottom electrodes as it exhibits one of the highest conductivities among known perovskite oxides while maintaining a high-quality surface and an epitaxy matching to a subsequently formed PZT layer. It also avoids unwanted magnetic interactions with the LBMO layer as the ferromagnetic Curie temperature of SRO is at most about 150 K.

After the formation of the SRO thin film, a 1.6 nm-thick PZT capping layer was grown in-situ at a temperature of 600° C. and at a purified oxygen pressure P_{O2} of 150 mTorr, before cooling down at a purified oxygen pressure P_{O2} of 200 Torr to minimize oxygen vacancy in the SRO layer. The SRO film formed on the STO (001) substrate was then taken out of vacuum, and the SRO film was patterned into long stripes of 20 μm width by standard photolithography followed by argon ion milling to form the SRO electrodes 502 (i.e. the bottom electrode 108 of FIG. 1). Because reheating the SRO film is inevitable after patterning, the very thin 1.6 nm-thick PZT capping layer formed was designed to prevent evaporation of the volatile RuO₂ in the SRO layer which may roughen the surface during the reheating process. Photolithography was done by spin-coating the sample with a photoresist (the AZ® 1252HS photoresist was used in the present embodiment), baking the spin-coated sample at a temperature of 120° C., exposing the heat-treated sample to an i-line UV light (365 nm wavelength) using a mask aligner (a SUSS-MJB4 Mask Aligner with UV lamp rated at 500 W was used in this case) for 3.5 s, followed by immersion of the exposed sample into a developer (the AZ® 726MIF developer was used in this embodiment) for 30 s. The soda-lime photomask used for photolithography was fabricated with patterns designed by a computer-aided design (CAD) software (e.g. Tanner EDA L-Edit™ software) which were fed into a laser writer equipped with a 4 mm write-head that can achieve a resolution of 1 μm. The argon ion milling used to pattern the SRO film into stripes was performed in a chamber with a base vacuum of 3×10⁻⁸ Torr and operating at an argon pressure of 7.5×10⁻⁴ Torr.

FIG. 5B shows a schematic diagram 510 to illustrate formation of the ferroelectric layer 512, the magnetic layer and the top electrode on the bottom SRO electrode 502 and the substrate 504 for forming the magnetic device.

In this second step of the two-step fabrication process, following the argon ion milling process of the first step to pattern the SRO film into stripes to form the SRO electrodes 502, the photoresist remaining on the SRO film was removed by acetone. The SRO electrodes 502 together with the STO (001) substrate 504 was then inserted into the PLD chamber for the growth of a single crystalline 40 nm-thick ferroelectric PZT layer 512, followed by a 2.4 nm-thick magnetic LBMO layer, both at a temperature of 600° C. and at a purified oxygen pressure P_{O2} of 150 mTorr. LBMO was chosen as the ferromagnetic material for the magnetic layer due to its high Curie temperature, having a more insulating property compared to La_{0.7}Sr_{0.3}MnO₃ (LSMO), and having dipolar-stabilized Bloch-type magnetic bubbles at >300 K. The heating process of the PLD in this second step advantageously cleans a surface of the sample despite breaking vacuum after the photolithography patterning process in the first step. After cooling down to room temperature at 200 Torr of oxygen, the sample was transferred in-situ at the base vacuum into the operationally connected DC magnetron sputtering chamber for the deposition of a 2 nm-thick Pt layer to form the top electrode. For the deposition of the Pt layer, the target-to-substrate distance was adjusted to be as long as 17.5 cm, with sputtering parameters set as power=10 W, voltage=360 V and current=0.028 A. Such combination maintains a slow Pt deposition rate of 0.0278 nm/s to ensure a good interfacial wetting and a strong DMI at the Pt/LMBO interface for supporting skyrmions in the LBMO layer. During the optimization phase of this work, the root-mean-square (rms) surface roughness after the growth of each layer was checked using an atomic force microscope and found to be ˜0.19 nm, ˜0.38 nm, ˜0.35 nm and ˜0.35 nm for the SRO, the PZT, the LBMO and the Pt surfaces, respectively. The slight increase of rms surface roughness measured on the PZT surface after the PZT growth was due to mild island growth in the PZT layer. Due to a large difference in optimal growth temperatures between the PZT layer and the LBMO layer, an intermediate temperature was found to bridge the gap, hence arriving at the compromise of mild island growth for the PZT layer while achieving the rms roughness of ˜0.35 nm for the LBMO surface. Finally, using similar photolithography and argon ion milling processes, the Pt/LBMO bilayer structure 514 (c.f. the top electrode 106 formed on the magnetic layer 102 as shown in FIG. 1) was patterned to remove unwanted regions of Pt/LBMO and to define top Hall bars as shown in FIG. 5B, while the ferroelectric PZT layer 512 remains completely covering the SRO electrodes 502 and a top surface of the STO (001) substrate 504. The resulted leakage current measured between the top Hall-bars and the bottom SRO electrodes 502 is <1 nA. The leakage current was measured by applying a potential difference 516 across the top Hall-bars and the bottom SRO electrodes 502. This potential difference 516 (e.g. in the form of a pulsed voltage) can be used for switching a polarization state of the ferroelectric PZT layer 512.

FIG. 6 shows an optical micrograph 600 of a top view of the magnetic device of FIG. 5B which comprises a Hall structure, in accordance with an embodiment.

The optical micrograph 600 shows areas with four different contrasts to indicate four different portions of the top view of the magnetic device. A first contrast 602 indicates areas in relation to the PZT layer 512 formed directly on the STO (001) substrate 504, a second contrast 604 indicates areas in relation to the PZT layer 512 formed on an SRO electrode 502, a third contrast 606 indicates areas in relation to portions of the Hall bar formed on the SRO electrode 502 having a heterostructure of Pt/LBMO/PZT/SRO, and a further contrast 608 indicates areas in relation to portions of the Hall ball (e.g. probes of the Hall bar) formed outside of the SRO electrode 502 and having a heterostructure Pt/LBMO/PZT formed on the STO (001) substrate 504. Also shown in the optical micrograph 600 are four probes connections (namely V+610, V−612, 1+614, 1-616) to the Hall bar structure used for Hall measurements of the Hall bar (e.g. to extract p_{xy} for measuring the THE due to polarization switching etc.). A good quality of the heterostructure grown can also be inferred from the optical micrograph 600 and this is further illustrated using the experimental results by atomic force microscopy, X-ray diffraction (XRD) and cross-sectional scanning transmission electron micrograph (STEM) (as shown in relation to FIGS. 13A to 13D below).

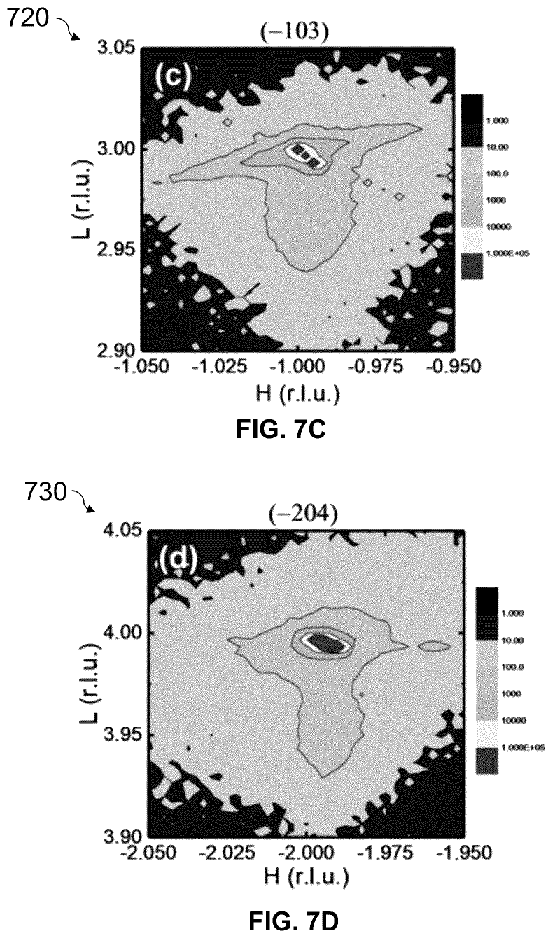

FIGS. 7A, 7B, 7C and 7D show experimental results obtained in relation to the heterostructure Pt/LBMO/PZT/SrRuO₃/SrTiO₃ (001) for investigating material quality of this heterostructure in accordance with an embodiment.

FIG. 7A shows a 2 Theta-Omega (2θ-ω) X-ray diffraction (XRD) scan around (002) of the heterostructure without ion milling (i.e. a non-patterned sample). X-ray diffraction was measured at a 4-circle high-resolution diffractometer. The peak positions are at 43.24° for PZT 702, 44.88° for LBMO 704, 46.12° for SRO 706 and 46.51° for STO (002) 708 measured at a wavelength of 1.5419 nm. This yields c-axis lattice parameters of 4.1841 Å, 4.0394 Å, 3.9364 Å, and 3.9053 Å (standard) for PZT, LBMO, SRO, STO respectively.

FIG. 7B shows an atomic force microscopy (AFM) topography scan 710 of the heterostructure Pt/LBMO/PZT/SrRuO₃/SrTiO₃ (001). The AFM topography scan indicates a rms surface roughness of about 0.31 nm, performed with an atomic force microscope using a cantilever with a force constant of ˜15 N/m and at a resonant frequency of ˜280 kHz.

FIG. 7C shows a XRD reciprocal space mapping 720 of the heterostructure for the (−103) crystallographic plane, while FIG. 7D shows a XRD reciprocal space mapping 730 of the heterostructure for the (−204) crystallographic plane. In both the reciprocal space mappings at (−103) and (−204), the (HKL) indices are with reference to the STO (001) substrate with lattice parameter 3.905 Å. Film peaks at HKL=(−0.995, 0, 2.95) and HKL=(−1.995, 0, 3.95) can be observed, indicating obvious c-axis tetragonal elongation of perovskite unit cell at >3.905 Å. The c-axis elongation is pivotal to the understanding of the relevant magnetoelectric coupling by orbital engineering, i.e.: C-type antiferromagnetic phase at PZT's polarization pointing towards LBMO (skyrmions annihilation), and ferromagnetic phase at polarization pointing away from LBMO (skyrmions creation). This is also consistent with the lattice parameters measured using scanning transmission electron microscopy (STEM) as shown in relation to FIG. 13 below. Conversely, if c-axis compression is found, then it would lead to a conclusion opposite to the result as shown in relation to the Hall Effect measurement.

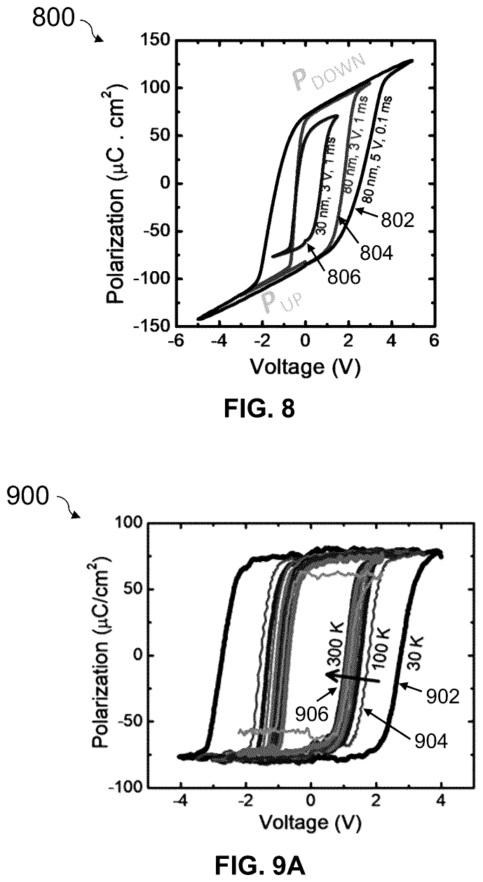

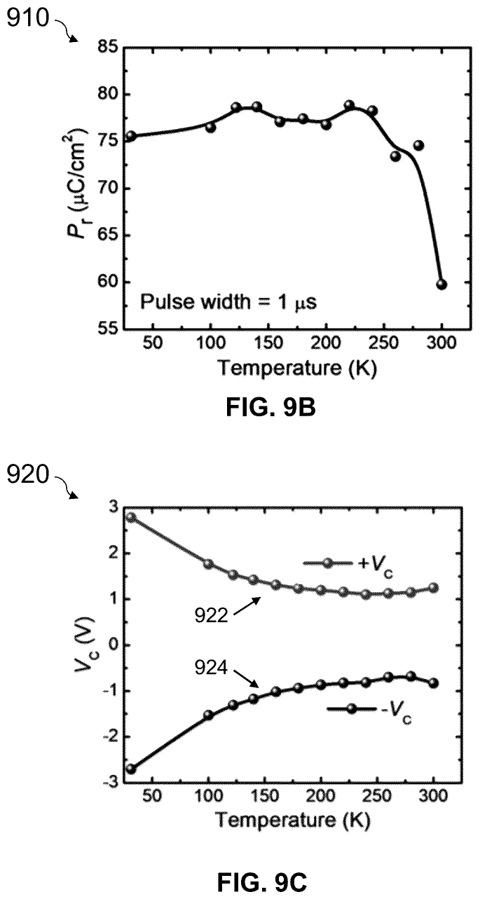

FIGS. 8 to 12 below involved electrical measurements performed on the magnetic device of FIG. 5B. In the present embodiments, electrical measurements were performed using a Quantum Design Physical Measurement System (PPMS). A Stanford Research SR830 Lock-in Amplifier was used to measure the Hall Effect by providing an alternating current (AC) source of 15 μA to 20 μA to the sample connected in series to a standard 100 kΩ resistor and with a frequency of 317.3 Hz. A Keithley SourceMeter® Model 2400 was used to provide DC voltage pulses (V_{gate} pulses) during Hall measurements, while the polarization (P)-V_{gate} hysteresis loops (see e.g. FIGS. 8 and 9A) were obtained from a Radiant Technologies Premier II Ferroelectric Tester. The Hall bar formed using the Pt/LBMO bilayer structure allows four-probe measurement of Hall Effect, while the two-probe switching of PZT's ferroelectric polarization can be performed using the top Pt and bottom SRO electrodes, e.g. by using ultrasonic wire bonding. As shown in relation to FIG. 5B, the P-V_{gate} hysteresis loops were obtained by electrical connections across the SRO electrode 502 and the Hall bar structure (i.e. the Pt electrode).

Due to strong spin-orbit coupling, the Pt electrode contributes an interfacial DMI for creating chiral magnetic ordering and Néel-type skyrmions in the LBMO layer. Besides, the free electrons of Pt also interact strongly with the LBMO magnetic moments via magnetic proximity effect (MPE) and Spin Hall Effect (SHE). Spin-Hall Anomalous and Topological Hall Effects (Sp-AHE and Sp-THE) can be picked-up via phase-sensitive lock-in detection by the SR-830 lock-in amplifier. The PZT layer 512 provides good insulation with resistance between the top Pt electrode and the bottom SRO electrodes 502 exceeding 10⁹Ω, thus avoiding interference noise between the AC Hall measurements and DC polarization switching.

FIG. 8 shows a graph 800 of polarization versus voltage (V_{gate}) loops measured across a PZT layer of a magnetic device with varying PZT thicknesses, pulse widths and pulse magnitudes in accordance with an embodiment. These data were obtained using the “hysteresis mode” in the Radiant Technologies Premier II Ferroelectric Tester before removal of a linear slope component as shown by the slanted hysteresis loops 802, 804, 806. The linear slope component relates to an unimportant dielectric component captured during the measurement.

As shown in the graph 800, three set of parameters were used. These are (i) voltage pulses having a full loop time (i.e. a hysteresis period) of 0.1 ms with a pulse magnitude of 5 V being applied to a 80 nm thick PZT layer as shown in relation to a hysteresis loop 802, (ii) voltage pulses having a full loop time of 1 ms with a pulse magnitude of 3 V being applied to a 80 nm thick PZT layer as shown in relation to a hysteresis loop 804, and (iii) voltage pulses having a full loop time of 1 ms with a pulse magnitude of 3 V being applied to a 30 nm thick PZT layer as shown in relation to a hysteresis loop 806.

The hysteresis loops 802, 804, 806 show a remanence of ˜75 μC/cm². Also shown in relation to the hysteresis loops 802, 804, a coercive voltage may increase slightly if the switching time (or the pulse width) is shortened.

FIGS. 9A, 9B and 9C show experimental results in relation to ferroelectric switching of the PZT layer 512 of the magnetic device as shown in relation to FIG. 5B in accordance with an embodiment.

FIG. 9A shows a graph 900 of polarization (P) versus voltage (V_{gate}) loops measured across the PZT layer at different temperatures. All the voltage loops were measured using pulsed voltages having a pulse width of 1 μs with a 1 ms full loop time. The data as shown in the graph 900 was obtained using the “remanent hysteresis mode” in the Radiant Technologies Premier II Ferroelectric Tester, with the linear background removed using the Ferroelectric Tester's software.

The graph 900 shows an evolution of the P-V_{gate} hysteresis loops with increasing temperatures from 30 K to 300 K, where increasing temperature reduces a coercive voltage of the P-V_{gate} hysteresis loops. The P-V_{gate} hysteresis loop 902 at a temperature of 30 K, the P-V_{gate} hysteresis loop 904 at a temperature of 100 K and the P-V_{gate} hysteresis loop 906 at a temperature of 300 K are labelled as shown in the graph 900.

Remnant polarization (Pᵣ) and coercive voltage (V_{C}) with respect to different temperatures can be extracted from the P-V_{gate} hysteresis loops in the graph 900 and these are shown in relation to FIGS. 9B and 9C, respectively.

FIG. 9B shows a graph 910 of remnant polarization (Pᵣ) versus temperature as extracted from the graph 900 of FIG. 9A. As shown in the graph 910, the remnant polarization (Pᵣ) is within a range of 75 μC/cm² to 78 μC/cm² from a temperature of 30 K to a temperature of around 240 K before decreasing to around 60 μC/cm² at a temperature of 300 K.

FIG. 9C shows a graph 920 of coercive voltage (V_{C}) versus temperature as extracted from the graph 900 of FIG. 9A comprising a plot 922 to indicate the positive coercive voltages and a plot 924 to indicate the negative coercive voltages. The plots 922, 924 show that the coercive voltage (V_{C}) decreases in an absolute magnitude with increasing temperature and plateaus at a temperature around 250 K to 300 K.

Besides the set-up for measuring the P-V_{gate} loops as described above, in the present embodiment, switching of the polarization can also be achieved by using a Keithley 2400 SourceMeter® at ±3 V with a voltage pulse width of 0.2 ms. For the results as shown in relation to FIGS. 10 to 12, a LabVIEW program was designed to control temperature and magnetic field of the sample using the PPMS, to provide voltage pulses using the Keithley 2400 SourceMeter®, and to perform Hall measurements using the SR830 lock-in amplifier. The remnant polarization was stable after each voltage pulse, and changes in the Hall Effect was observed within a magnetic field range of ±3 T.

FIG. 10 shows graphs of resistivity p_{xy} versus magnetic field μ₀H to illustrate Hall effect tuning by switching the ferroelectric polarization at different temperatures in accordance with an embodiment. The samples used included a 2.4 nm thick LBMO layer, having a same thickness as the LBMO in the magnetic device of the exemplary embodiments. The resistivity p_{xy} for each magnetic field sweep of ±3 T was measured at various temperatures after each V_{gate} pulse of ±3V of 0.2 ms width. It should be appreciated that 0.2 ms is the shortest pulse width that can be output from the Keithley 2400 SourceMeter®, but is longer than what is actually required to switch the PZT's polarization.

FIG. 10 shows graphs 1000 of resistivity p_{xy} versus magnetic field μ₀H for a voltage pulse width of 0.2 ms at temperatures of 150 K, 200 K, 250 K and 300 K. The graph 1002 shows the resistivity p_{xy} versus magnetic field μ₀H plot at a temperature of 150 K after an application of a +3 V voltage pulse 1010 and after an application of a −3 V voltage pulse 1012. The graph 1004 shows the resistivity p_{xy} versus magnetic field μ₀H plot at a temperature of 200 K after an application of a +3 V voltage pulse 1014 and after an application of a −3 V voltage pulse 1016. The graph 1006 shows the resistivity p_{xy} versus magnetic field μ₀H plot at a temperature of 250 K after an application of a +3 V voltage pulse 1018 and after an application of a −3 V voltage pulse 1020. The graph 1008 shows the resistivity p_{xy} versus magnetic field μ₀H plot at a temperature of 300 K after an application of a +3 V voltage pulse 1022 and after an application of a −3 V voltage pulse 1024.

From the graphs of 1002, 1004, 1006 and 1008, it is evidenced that THE hump peaks were observed when +3 V voltage pulses were used (i.e. when the polarization of the ferroelectric PZT layer is pointing down (P_{DOWN}) and away from LBMO layer) but THE hump peaks were suppressed when −3 V voltage pulses were used (i.e. when the polarization of the ferroelectric PZT layer is pointing upward (P_{UP}) towards the LBMO layer). Therefore, the P_{DOWN} polarization state corresponds to magnetic skyrmion creation while the P_{UP} polarization state corresponds to magnetic skyrmion annihilation. As shown in the graphs 1000, for P_{DOWN}, the THE peaks were observed at around ±0.2 T indicating a presence of dense magnetic skyrmions which can be saturated into collinear ferromagnetic by a larger magnetic field (see e.g. the illustrations at FIG. 3A). Conversely, the absence of the THE peaks for the P_{UP} state, indicates an absence of magnetic skyrmions in the LBMO layer.

As shown in relation to the results of FIG. 10, reversible and non-volatile manipulation of the THE was observed at near room temperatures, indicating the creation and annihilation of magnetic skyrmions upon switching of the PZT ferroelectric polarization.

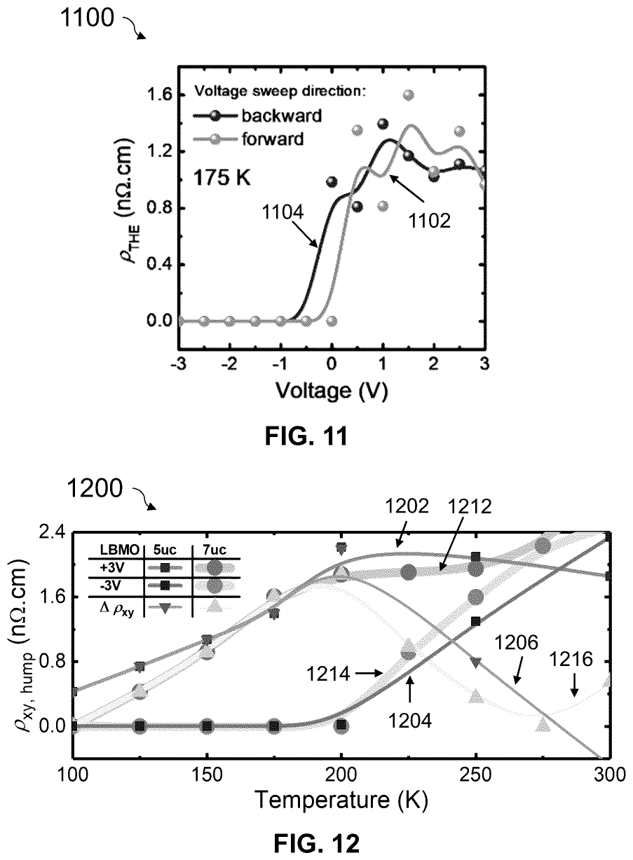

FIG. 11 shows a graph 1100 of THE resistivity P_{THE} versus an applied voltage across the PZT layer 512 of the magnetic device of FIG. 5B at a temperature of 175 K and at a magnetic field of 0.2 T in accordance with an embodiment.

By fixing the temperature at 175 K and the magnetic field at 0.2 T near where the THE peaks are observed, Hall resistivity ρ_{xy} was measured with sweeping the applied voltage V_{gate} across the PZT layer 512. A forward sweep 1102 and a backward sweep 1104 of the applied voltage V_{gate} are shown in the graph 1100, which traces a hysteresis loop. This indicates that the Hall response as shown in the graph 1100 is directly related to the PZT's ferroelectric polarization. From the absence of THE peaks at P_{UP}, it can be inferred that the magnetic energy landscape is changed to become unfavourable for magnetic skyrmion formation. Here, it is noted that the domain wall energy σ_{DW}=4\sqrt{AₑₓK_{eff}}−πDᵢₙₜ>0, where K_{eff}=K_{U}+μ₀Mₛₐₜ²/2 is the effective anisotropy with the dipolar interaction accounted, while Aₑₓ, K_{U} and Dᵢₙₜ and Mₛₐₜ are the exchange stiffness related to T_{C}, uniaxial anisotropy, interfacial DMI and saturation magnetization. Upon switching the ferroelectric polarization, modulation of all three parameters Aₑₓ, K_{U} and Dᵢₙₜ are possible, and the more dominant parameter for the present switching will be discussed later in relation to FIGS. 14C and 14D.

FIG. 12 shows a graph 1200 of Topological Hall Effect (THE) resistivity ρ_{THE} versus temperature for a 2.0 nm thick (i.e. 5 uc) LBMO layer and a 2.8 nm thick (i.e. 7 uc) LBMO layer at applied voltages of +3 V and −3 V in accordance with an embodiment.

The plots 1202 and 1204 relates to the ρ_{THE} versus temperature plot at an applied voltage of +3 V and −3 V, respectively, for the 2.0 nm thick LBMO layer. The plot 1206 shows the difference in Δρ_{THE} between the +3 V plot 1202 and the −3 V plot 1204 for this 2.0 nm thick LBMO layer. Similarly, the plots 1212 and 1214 relates to the ρ_{THE} versus temperature plot at an applied voltage of +3 V and −3 V, respectively, for the 2.8 nm thick LBMO layer. The plot 1216 shows the difference in Δρ_{THE} between the +3 V plot 1212 and the −3 V plot 1214 for this 2.8 nm thick LBMO layer.

Although the tuning efficacy reduces with increasing temperature as shown in the graph 1200, the trend as shown in the graph 1200 suggests that it may be possible to retain a significant Δρ_{THE} up to room temperature by increasing the LBMO thickness.

FIGS. 13A, 13B, 13C and 13D show experimental results obtained using scanning transmission electron microscopy (STEM) of a heterostructure Pt/LBMO/PZT/SRO of the magnetic device of FIG. 5B in accordance with an embodiment. The sample was cut by a focused ion beam directly at the centre of a Hall bar of the magnetic device and was imaged under a double aberration-corrected FEI Titan³™ Themis 60-300 Microscope equipped with a high brightness field emission gun (X-FEG).

FIG. 13A shows an energy dispersion spectroscopy (EDS) mapping 1300 of a cross-section of the sample, while FIG. 13B shows a high-angle annular dark field (HAADF) image 1310 of a cross-section of the sample. Both the EDS mapping 1300 and the HAADF image 1310 were performed at room temperature.

The EDS mapping 1300 of FIG. 13A shows clear layers with minimal inter-diffusion. The EDS mapping 1300 can be used to extract information in relation to the thickness of each layer in the heterostructure. On the other hand, the HAADF image 1310 as shown in FIG. 13B allows measurement of the a-axis and c-axis lattice parameters of the LBMO layer of the heterostructure, which is ˜4.0 Å and ˜4.06 Å respectively. The ratio of c/a is therefore 1.0154 which is more than 1, indicating c-axis elongation of the LBMO layer.

As observed from the HAADF image 1310 for the other layers of the heterostructure, it is indicated that lattice parameters along all 3-axes show strain relaxation mainly in the PZT layer (it was assumed that a≈b in this case as it is well-established that a≈b for films grown on STO (001)). The c-axis lattice parameter values of the different layers were also extracted and these are consistent with the results obtained using the 2theta-omega XRD scan around (002) as shown in relation to FIG. 7A.

FIG. 13C shows a cationic displacement mapping 1320 near the LBMO/PZT interface of the heterostructure and FIG. 13D shows a cationic displacement mapping 1330 near the PZT/SRO interface. Dotted lines as shown in the cationic displacement mappings 1320, 1330 denote interfaces between two different materials, where the dotted line 1322 denotes an interface between Pt and LBMO, the dotted line 1324 denotes an interface between LBMO and PZT, and the dotted line 1332 denotes an interface between PZT and SRO.

The emergence of electric polarization in the LBMO layer as shown in relation to the arrows is observed in the cationic displacement mapping 1320. This extra contribution of polarization could explain the observed ultralow switching voltage of ±0.1 V at the onset of the tuning effect (i.e. Δρ_{THE} between forward sweep and backward sweep) as shown in relation to FIG. 11. As a control, no electric polarization was observed in the electrical conductor SRO as shown in the cationic displacement mapping 1330 of FIG. 13D.

The above results provide insights into the mechanisms in relation to tuning of the LBMO's magnetic properties by switching the ferroelectric polarization of PZT. In relation to a design perspective of the heterostructure Pt/LBMO/PZT/SRO, given that no single-crystalline oxide can be grown on amorphous Pt, it is therefore preferred that the LBMO layer be grown on the PZT layer prior to forming the Pt layer on the LBMO layer to form the Pt/LBMO interface. The resulted LBMO crystallinity is less than that of epitaxial LBMO//STO (001), as evident from a higher surface roughness of 0.3 nm extracted from the AFM scan as shown in relation to FIG. 7B and the full-width-half-maximum (FWHM) at XRD ω-rocking curve of (002) as shown in relation to FIG. 7A. These suggests a mild Stranski-Krastanov (SK) growth in the LBMO layer. This factor reduces the Mₛₐₜ of the LBMO layer grown on the PZT layer, in comparison to that of epitaxial LBMO//STO (001).

The valence electronic configuration in perovskite hole-doped manganites is known to be 3d t_{2g}³ e_{g}^{1-x} where x is the doping percentage, and all electrons are spin-up since the Hund's splitting is way higher than the crystal-field splitting in these manganites. Following the consensus of magnetoelectric coupling established at PZT/La₁₋ₓSrₓMnO₃(LSMO) interfaces, hole depletion is expected at polarization pointing towards LSMO, which reduces the Mn^{(3+x)+} valence and promotes z-direction (interlayer) double-exchange (DE) via 3d_{3z}_{²}₋ᵣ_{²} orbitals, thus increasing the Mₛₐₜ in the LSMO layer. On the other hand, polarization pointing away from LSMO weakens the z-direction DE but promotes interlayer super-exchange (SE), whereas the xy-direction DE remains strong in this case, thus resulting in a lower Mₛₐₜ in the LSMO layer due to the presence of an A-type antiferromagnetic (A-AF) “dead-layer” near the PZT/LSMO interface. Such phenomenon has been shown with PZT-on-LSMO structures and Density Functional Theory (DFT) calculations.

This is in contrast to the present case for the heterostructure Pt/LBMO/PZT/SRO where the Mₛₐₜ for P_{DOWN} is stronger than that of P_{UP}, in other words, that Pᵤₚ towards LBMO results in a weakened apparent Hall Effect, opposite to that obtained for PZT/LSMO structure. Particularly, it is noted that the tuning of LBMO's magnetic properties for the present heterostructure is directly due to polarization switching, thus films' quality issue is excluded in comparing the effect of the polarization direction. As discussed in relation to FIG. 7B, the LBMO's c-axis lattice parameter of 4.04 Å obtained in the present case is far larger than its bulk value 3.88 Å, as measured by XRD. This is opposite to the structures involved in the aforementioned PZT/LSMO structures where the LSMO//STO (001) (formed below the PZT) is usually under in-plane tensile, c-axis compression induced by the STO (001) substrate. In the present case, the crystal field in a c-axis elongated manganite unit cell mandates lower 3d_{3z}_{²}₋ᵣ_{²} orbital energy compared to that of the 3dₓ_{²}_{-y}_{²} orbital, resulting in the 3d_{3z}_{²}₋ᵣ_{²} and 3dₓ_{²}_{-y}_{²} orbitals being over- and under-populated by electrons, respectively. In this case, polarization towards LBMO (Pᵤₚ) further redistributes or siphons electrons from the 3dₓ_{²}_{-y}_{²} orbital to the 3d_{3z}_{²}₋ᵣ_{²} orbital, thereby promoting z-direction DE but also xy-direction SE, creating a C-type antiferromagnetic (C-AF) dead layer. Vice versa, polarization away from LBMO (P_{DOWN}) would restore a more balanced DE among all directions, akin to cancelling the strain effect. This way, the Mₛₐₜ for P_{DOWN} is stronger than that of P_{UP}.

FIGS. 14A, 14B, 14C and 14D show diagrams to illustrate the aforementioned mechanism of the LBMO/PZT magneto-electric response in accordance with an embodiment.

Particularly, FIG. 14A shows a schematic diagram 1400 to illustrate a first scenario where polarization of the PZT layer 1402 is pointing away from the LBMO layer 1404 (i.e. P_{DOWN}) and FIG. 14B shows a schematic diagram 1410 to illustrate a second scenario where polarization of the PZT layer 1412 is pointing towards the LBMO layer 1414 (i.e. P_{UP}). For the polarization of the PZT layer 1402 pointing away from the LBMO layer 1404 as shown in FIG. 14A, the LBMO is ferromagnetic. For the polarization of the PZT layer 1412 pointing towards the LBMO layer 1414, the LBMO becomes C-type antiferromagnetic. Illustrations showing the double-exchange (J_{FM}) and super-exchange (J_{AF}) pathways among 3dₓ_{²}_{-y}_{²} and 3d_{3z}_{²}₋ᵣ_{²} orbitals (drawn overlapping each other) via the O2p orbitals are also shown in the schematic diagrams 1400, 1410 for each PZT polarization state. The t_{2g} orbitals containing 3μB magnetization are not shown. Orbitals elongation or suppression are illustrated to show the electric field effect by the polarization. Ferromagnetic arrangement of magnetic moments and C-type antiferromagnetic arrangement of magnetic moments are also indicated by the arrows overlaid on the 3dₓ_{²}_{-y}_{²} and 3d_{3z}_{²}₋ᵣ_{²} orbitals in the schematic diagrams 1400, 1410 respectively. The progressive canting towards the top Pt/LBMO interface by the action of DMI is also illustrated in both schematic diagrams 1400, 1410.

The schematic diagrams 1400, 1410 as shown in relation to FIGS. 14A and 14B show that the electrostatic doping and strain effects act in tandem in deciding the tuning polarity of interfaces between hole-doped manganite and PZT (or other P_{[001]} ferroelectrics in general).

FIG. 14C shows a graph 1420 of simulated topological charge density (TCD) versus magnetic field μ₀H_{z} for the first scenario as shown in relation to FIG. 14A (i.e. P_{DOWN}), and FIG. 14D shows a graph 1430 of simulated topological charge density (TCD) versus magnetic field μ₀H_{z} for the second scenario as shown in relation to FIG. 14B (i.e. P_{UP}). These graphs 1420, 1430 were obtained by micromagnetic MUMAX3 simulations for the cases of polarization pointing away from (i.e. P_{DOWN}) and towards (i.e. P_{UP}) the LBMO layer, where they differ by a positive (ferromagnetic) and negative (antiferromagnetic) signs in Aₑₓ respectively.

The graph 1420 show a plot 1422 in relation to a forward sweep of the magnetic field and a plot 1424 in relation to a backward sweep of the magnetic field. Also shown in FIG. 14C are simulated snapshots of magnetic moments in the LBMO layer for different magnetic fields. The snapshot 1426 corresponds to a magnetic field at −1.0 T, the snapshot 1428 corresponds to a magnetic field at −0.2 T, the snapshot 1430 corresponds to a magnetic field at 0 T, the snapshot 1432 corresponds to a magnetic field at +0.2 T and the snapshot 1434 corresponds to a magnetic field at +1.0 T. The snapshots show ferromagnetic textures evolution from stripes (see e.g. the snapshot 1430) to skyrmion lattice (see e.g. the snapshot 1432 or 1428) to saturation (see e.g. the snapshot 1434 (i.e. uniform magnetization pointing up) or 1426 (i.e. uniform magnetization pointing down)) with increasing magnetic field for the case with P_{DOWN}.

The graph 1440 show a plot in relation to a forward sweep of the magnetic field. Similar to FIG. 14C, simulated snapshots of magnetic moments in the LBMO layer for different magnetic fields are shown in FIG. 14D. The snapshots 1442, 1444, 1446, 1448, 1450 correspond to a magnetic field at −1.0 T, −0.2 T, 0 T, +0.2 T and +1.0 T, respectively. The snapshots 1442, 1444, 1446, 1448, 1450 all show antiferromagnetic domain wall textures for the case with P_{UP}.

For the micromagnetic MUMAX3 simulations performed, as slightly weaker magnetic properties can be expected by growing LBMO on PZT, the magnitudes of Aₑₓ, Mₛₐₜ and K_{U} were reduced in the simulation to 2.5 pJ/m, 250 kA/m and 7 kJ/m³ respectively as compared to the parameters used in relation to FIG. 4 earlier, while ensuring that the peak-TCD fields match with their corresponding experimental THE results. Therefore, at the P_{DOWN} ferromagnetic state with Aₑₓ=+2.5 pJ/m, a skyrmion-lattice can be obtained at μ₀H_{z}=±0.2 T as shown in FIG. 14C. As the sign of Aₑₓ is reversed (−2.5 pJ/m) at the P_{UP} state to represent the C-AF phase, the resulted domain evolution becomes almost insensitive to the magnetic field, with small residual TCD values likely originating from the antiferromagnetic domain walls. Similar physical mechanism as explained above is expected also for a low temperature range of 150 K-250 K. On the other hand, at higher temperatures, increase in thermal fluctuations weakens the C-AF phase rendering it indistinguishable from the ferromagnetic one and producing a noticeable THE as well. This is evidenced for example in the graphs 1000 as shown in relation to FIG. 10.

Embodiments as described in the present disclosure therefore provide a magnetic device comprising: (i) a magnetic layer having a ferromagnetic phase to support magnetic skyrmions and an antiferromagnetic phase to annihilate magnetic skyrmions, (ii) a ferroelectric layer adapted to magnetoelectrically couple with the magnetic layer to cause the magnetic layer to transit between the ferromagnetic phase and the antiferromagnetic phase in response to a polarization state of the ferroelectric layer, and (iii) a first electrode and a second electrode adapted to receive an applied voltage for switching the polarization state of the ferroelectric layer to control a phase transition of the magnetic layer between the ferromagnetic phase and the antiferromagnetic phase to create or annihilate magnetic skyrmions in the magnetic layer.

In the exemplary embodiment having a heterostructure of Pt/LBMO/PZT/SRO, it was shown that the THE tuning by PZT's ferroelectric switching is related to a phase transition between C-type antiferromagnetic (at P_{UP}) and ferromagnetic (at P_{DOWN}) in LBMO due to electrostatic doping by the polarization surface charge of the PZT. The electrostatic doping effectively siphons electrons between the Mn e_{g}-orbitals i.e. the positive bound charge of P_{UP} attracts more electrons to occupy the 3d_{3z}_{²}₋ᵣ_{²} orbitals due to their proximity to the interface by pd σ-bonds, while on the other hand, the negative bound charge of P_{DOWN} causes more electrons to occupy the 3dₓ_{²}_{-y}_{²} orbitals. The above observations are under the premise that the LBMO layer grown on the PZT layer is subjected to an in-plane compression and a c-axis elongation, which resulted in the c/a>1 tetragonal crystal field that puts the 3d_{3z}_{²}₋ᵣ_{²} orbital as a lower energy orbital as compared to the 3dₓ_{²}_{-y}_{²} orbital.

In this way, the C-type antiferromagnetic state is slightly more stable theoretically, since the ferromagnetic double-exchange is good along the z-direction but is poor along the xy-directions, thus the antiferromagnetic super-exchange via the t_{2g} orbitals would dominate along the xy-directions. The P_{DOWN} state can restore a more balanced ferromagnetic double-exchange along all directions by repopulating the 3dₓ_{²}_{-y}_{²} orbitals. Also, in the present example, electrostatic doping effect is observed to persist from 100 K to 275 K with high consistency among LBMO thicknesses in the range of 2.0 nm to 2.8 nm. For the present material system/heterostructure, the response to ferroelectric polarization switching is expected to vanish at a LBMO thickness of less than 2.0 nm due to dominating C-type antiferromagnetic at lower thicknesses and also to vanish at a LBMO thickness larger than 2.8 nm due to dominating ferromagnetic at large thicknesses.

The present disclosure shows magnetoelectric coupling at PZT/manganite interfaces for controlling magnetic skyrmions using a phase transition between ferromagnetic and C-type antiferromagnetic in the manganite layer. Particularly, in the example with the heterostructure Pt/LBMO/PZT/SRO, the in-plane compression and the c-axis elongation results in the c/a>1 tetragonal crystal field which puts the 3d_{3z}_{²}₋ᵣ_{²} orbital as a lower energy orbital as compared to the 3dₓ_{²}_{-y}_{²} orbital. This is contrasted with earlier work where growth of LSMO on STO (001) substrate resulted in in-plane tensile strain (c/a<1) condition which induces a phase transition between A-type antiferromagnetic and ferromagnetic in the LSMO layer.

The heterostructure Pt/LBMO/PZT/SRO provides the following advantages: (1) the magnetic proximity effect (MPE) provided by the Pt layer allows direct probing of magnetic properties via Hall Effect; (2) the magnetoelectric response of LBMO/PZT provided by ferroelectric polarization switching results in creation/annihilation of magnetic skyrmions and qualify as a high-temperature artificial multiferroic skyrmion-host; and (3) the competition between electrostatic doping and strain in tuning orbital occupancy and deciding the resulting magnetic phases were explored and provided insights into designing future heterostructures for potential applications.

The magnetic device utilising magnetoelectric coupling as afore-described can be used to form skyrmion field-effect transistors, skyrmion racetrack memory (e.g. low threshold current density (J_{C}) is required for driving skyrmions' motion by spin-torques), skyrmion-based neuromorphic computing, or hybrid skyrmion-superconductor heterostructures for braiding Majorana Bound States in topological quantum computing. There are also potential applications where skyrmion field-effect transistors can be integrated with the tunnelling non-collinear magnetoresistance (TNcMR), to find application in building neuromorphic/stochastic networks. The magnetic device of the present embodiments can also be developed to integrate with silicon platforms compatible to the present CMOS industry.

It should be appreciated that although LBMO has been used as an example for the magnetic layer above, other suitable magnetic layer exhibiting transition between a ferromagnetic phase and an antiferromagnetic phase that can be triggered by switching an applied electric field direction can be used.

For everyday application as memory devices, the magnetic layer may have a Curie temperature (T_{C}) above room-temperature. Further, the magnetic layer may have a perovskite crystal structure to grow epitaxially on a known ferroelectric oxide to ease growth of such heterostructure or fabrication of the magnetic device.

A suitable class of material for use as a magnetic layer of the magnetic device includes ferromagnetic manganites—R³⁺₍₁₋ₓ₎ A²⁺₍ₓ₎MnO₃, where R³⁺ is a rare-earth ion and A²⁺ is an alkali-earth ion. The present example of La_{0.5}Ba_{0.5}MnO₃ (LBMO) is a material of this class. It is noted that using different R and/or A in this class may produce similar results as shown for LBMO in the exemplary embodiment. The composition in relation to the parameter x can also be altered but this has to be changed with caution as this affects a magnetic state of the magnetic material.

In the exemplary embodiments above, PZT was used as the ferroelectric layer due to its remnant polarization (Pᵣ=˜70 μC/cm²) being large enough to induce the magnetoelectric coupling in LBMO, abrupt polarization switching (square hysteresis loop) and good electrical insulation due to its bandgap 3.2 eV, reaching a resistivity of 1.3×10⁷ Ω·m in a 40 nm-thick film. Other options for the ferroelectric layer may include BiFeO₃ (Pᵣ ˜70 μC/cm²) and NaNbO₃ (Pᵣ˜20 μC/cm²) which can be used to replace the toxic Pb content in PZT.

In relation to the electrodes, the bottom electrode (i.e. the second electrode adjacent to the ferroelectric layer) of the exemplary embodiment includes SrRuO₃ but other suitable material which is electrically conductive, stable and is easy to achieve layer-by-layer or step-flow growth mode in thin film deposition can be used. Examples of this include metallic perovskite oxides such as CaRuO₃, LaNiO₃, La_{0.7}Sr_{0.3}MnO₃ or SrCO₃. For the top electrode (i.e. the first electrode adjacent to the magnetic layer), other suitable metals that (i) has a strong spin-orbit coupling, (ii) can contribute to an interfacial Dzyaloshinskii-Moriya interaction (DMI) in the magnetic layer for creating chiral magnetic ordering and Néel-type skyrmions in the magnetic layer, and stabilizing these magnetic skyrmions in the magnetic layer; and (iii) have free electrons that interact with magnetic moments in the magnetic layer via the magnetic proximity effect (MPE) and the Spin Hall Effect (SHE). Possible examples include heavy metals such as tungsten (W), rhenium (Re), palladium (Pd) and gold (Au) etc. which can contribute DMI and supports Skyrmions in the magnetic layer.

Further, although specific apparatus or equipment for growing the samples and measuring the Hall effects or other material parameters were used, it should be appreciated that other suitable apparatus or equipment can be used to achieve similar growth of the heterostructures and/or to measure the Hall effects and/or to measure other material parameters of the samples.

It is also note that the present embodiments do not involve multiferroic such as BiFeO₃ (BFO). Taking BFO as an example, BFO thin films typically have a large leakage current and therefore are required to be grown relatively thick (>300 nm) to provide good ferroelectric switching. This is not desired as it reduces throughput and shortens the lifetime of fabrication equipment (laser of pulsed laser deposition (PLD)). Further, a thick BFO film may cause surface roughening and is therefore detrimental to the growth of subsequent layers formed on the BFO film.

Other alternative embodiments of the invention include: (i) alternative arrangements of the heterostructure e.g. a first electrode can be first grown on a suitable substrate, followed by the deposition of the magnetic layer on the first electrode, the formation of the ferroelectric layer on the magnetic layer and lastly the formation of a second electrode on the ferroelectric layer; (ii) having a different composition (e.g. x-value) for the La₁₋ₓBaₓMnO₃ layer; (iii) having a different thickness range for the LBMO layer besides 2.0 nm to 2.8 nm, for example, increasing a thickness of the LBMO layer with varying a composition of the LBMO layer to achieve similar effects; (iv) using other suitable substrate layer that enables consistent growth of selected electrode and/or ferroelectric layer other than the SrTiO₃ (001) substrate used in the example. An example of a possible substrate includes a Si (001) substrate; (v) a barrier layer (e.g. an ultrathin barrier layer) formed between the ferroelectric layer and the magnetic layer (e.g. acting as a capping layer for improving subsequent growth of the ferroelectric layer or the magnetic layer etc.); (vi) other structures or methods besides a Hall bar structure for detecting a presence or an absence of skyrmions in the magnetic layer; (vii) different pairs of electrodes (e.g. different material pairs) for switching a polarization state of the ferroelectric layer and for used in detecting a presence of magnetic skyrmions in the magnetic layer; (viii) use of deep-UV photolithography in place of the photolithography process as afore-described which can generate smaller feature size for the magnetic device; (ix) use of RF-sputtering in place of the PLD deposition processes as afore-described for higher through-put; (x) integrating high quality SrTiO₃ thin film on silicon using a strontium silicide interfacial buffer layer for potential CMOS integration and to avoid high costs associated with a SrTiO₃ (001) single crystal substrate; (xi) detection of the presence (i.e. creation) and absence (i.e. annihilation) of magnetic skyrmions in the magnetic device by suitable imaging (e.g. using magnetic force microscopy, Lorentz transmission electron microscopy, nitrogen-vacancy (NV) magnetometry etc.); (xii) the platinum layer having a thickness in a range from 2 nm to 5 nm; and (xiii) Hall bars formed having different dimensions as shown in the exemplary embodiment in relation to FIG. 6.

Although only certain embodiments of the present invention have been described in detail, many variations are possible in accordance with the appended claims. For example, features described in relation to one embodiment may be incorporated into one or more other embodiments and vice versa.

The teachings of all patents, published applications and references cited herein are incorporated by reference in their entirety.

While example embodiments have been particularly shown and described, it will be understood by those skilled in the art that various changes in form and details may be made therein without departing from the scope of the embodiments encompassed by the appended claims.

What is claimed is:

1. A magnetic device comprising:
a magnetic layer having a ferromagnetic phase to support magnetic skyrmions and an antiferromagnetic phase to annihilate magnetic skyrmions, the magnetic layer being capable of transiting between the ferromagnetic phase and the antiferromagnetic phase;
a ferroelectric layer adapted to magnetoelectrically couple with the magnetic layer to cause the magnetic layer to transit between the ferromagnetic phase and the antiferromagnetic phase in response to a polarization state of the ferroelectric layer, the polarization state includes a first polarization state corresponding to the ferromagnetic state and a second polarization state corresponding to the antiferromagnetic state; and
a first electrode and a second electrode sandwiching the magnetic layer and the ferroelectric layer, the first electrode and the second electrode being adapted to receive an applied voltage for switching the polarization state of the ferroelectric layer to control a phase transition of the magnetic layer between the ferromagnetic phase and the antiferromagnetic phase to create or annihilate magnetic skyrmions in the magnetic layer.

2. The magnetic device of claim 1, wherein the magnetic layer includes a (La,Ba)MnO₃ (LBMO) layer and the ferroelectric layer includes a lead zirconate titanate (PZT) layer.

3. The magnetic device of claim 2, wherein the magnetic layer comprises La_{0.5}Ba_{0.5}MnO₃ and has a thickness from 2.0 nm to 2.8 nm.

4. The magnetic device of claim 2, wherein the first electrode is formed adjacent to the magnetic layer and the second electrode is formed adjacent to the ferroelectric layer, and wherein the first electrode comprises a platinum (Pt) layer.

5. The magnetic device of claim 4, wherein the second electrode includes a monostrontium ruthenate (SrRuO₃) layer.

6. The magnetic device of claim 4, wherein the platinum layer and the magnetic layer are patterned in a form of a Hall bar to measure a Hall effect in the magnetic layer.

7. The magnetic device of claim 2, further comprising a SrTiO₃ (001) substrate, wherein the magnetic layer, the ferroelectric layer the first electrode and the second electrode are formed on the SrTiO₃ (001) substrate.

8. The magnetic device of claim 1, wherein the magnetic layer is formed immediately adjacent to the ferroelectric layer.

9. A method for forming a magnetic device, the method comprising:
forming a magnetic layer having a ferromagnetic phase to support magnetic skyrmions and an antiferromagnetic phase to annihilate magnetic skyrmions, the magnetic layer being capable of transiting between the ferromagnetic phase and the antiferromagnetic phase;
forming a ferroelectric layer adapted to magnetoelectrically couple with the magnetic layer to cause the magnetic layer to transit between the ferromagnetic phase and the antiferromagnetic phase in response to a polarization state of the ferroelectric layer, the polarization state includes a first polarization state associated with the ferromagnetic state and a second polarization state associated with the antiferromagnetic state; and
forming a first electrode and a second electrode sandwiching the magnetic layer and the ferroelectric layer, the first electrode and the second electrode being adapted to receive an applied voltage for altering the polarization state of the ferroelectric layer to control a phase transition of the magnetic layer between the ferromagnetic phase and the antiferromagnetic phase to create or annihilate magnetic skyrmions in the magnetic layer.

10. The method of claim 9, wherein the magnetic layer includes a (La,Ba)MnO₃ (LBMO) layer and the ferroelectric layer includes a lead zirconate titanate (PZT) layer, forming the magnetic layer and forming the ferroelectric layer includes pulse laser depositing the (La,Ba)MnO₃ (LBMO) layer and pulsed laser depositing the lead zirconate titanate (PZT) layer in-situ.

11. The method of claim 10, wherein the magnetic layer comprises La_{0.5}Ba_{0.5}MnO₃ and has a thickness from 2.0 nm to 2.8 nm.

12. The method of claim 10, further comprising forming the first electrode adjacent to the magnetic layer and forming the second electrode adjacent to the ferroelectric layer, wherein the first electrode includes a platinum (Pt) layer.

13. The method of claim 12, wherein the second electrode includes a monostrontium ruthenate (SrRuO₃) layer.

14. The method of claim 12, further comprising patterning the platinum layer and the magnetic layer in a form of a Hall bar for measuring a Hall effect in the magnetic layer.

15. The method of claim 12, further comprising forming the platinum layer by sputtering, wherein the platinum layer has a thickness in a range from 2 nm to 5 nm.

16. The method of claim 10, further comprising forming the magnetic layer, the ferroelectric layer the first electrode and the second electrode on a SrTiO₃ (001) substrate.

17. The method of claim 9, further comprising forming the magnetic layer immediately adjacent to the ferroelectric layer.
